(19) United States
(12) Patent Application Publication
(10) Pub. No.: US 2010/0073267 A1
(43) Pub. Date: Mar. 25, 2010

(54) Image display device

(75) Inventors: Hajime Akimoto, Ome (JP); Hiroshi Kageyama, Hachioji (JP); Takeo Shiba, Kodaira (JP)

Correspondence Address: Stanley P. Fisher;Reed Smith LLP, Suite 1400, 3110 Fairview Park Drive, Falls Church, VA, 22043-4503, US

(73) Assignee: Hitachi Displays, Ltd.

(21) Appl. No.: 12/588,205

(22) Filed: Oct. 7, 2009

Related U.S. Application Data
(63) Continuation of application No. 10/757,588, filed on Jan. 15, 2004, now abandoned.

(30) Foreign Application Priority Data
May 15, 2003 (JP) P2003-136690

(51) Int. Cl. G09G 3/30

(52) U.S. Cl. 345/76

(57) ABSTRACT

Disclosed herewith an image display device capable of displaying high quality images and preferred for reducing the manufacturing cost. The image display device is provided with illuminating state controlling state for controlling the illuminating state or non-illuminating state and constant voltage supply for supplying a constant voltage to each pixel through a signal line when the illuminating state is selected for the pixel.

### CROSS REFERENCE TO RELATED APPLICATIONS

This application is a Continuation Application of U.S. application Ser. No. 10/757,588 filed on Jan. 15, 2004. The present application claims priority from U.S. application Ser. No. 10/757,588 filed on Jan. 15, 2004, which claims priority from Japanese patent application 2003-136690 filed May 15, 2003 the entire disclosure of which is hereby incorporated by reference.

### FIELD OF THE INVENTION

The present invention relates to a high quality image display device, more particularly to an image display device preferred for cost reduction.

### BACKGROUND OF THE INVENTION

Hereunder, conventional techniques related to such image display devices will be described briefly with reference to FIGS. 18 and 19.

FIG. 18 shows a circuit diagram of a pixel of an electro-luminescent display device manufactured according to a conventional technique. While pixels are disposed like a matrix in the display area of the electro-luminescent display device, only one pixel is shown in FIG. 18 to simplify the description. Each pixel 110 is provided with an organic EL (Electro-Luminescent) element 101 provided as an electro-luminescent element and the cathode terminal of the organic EL element is connected to a common ground. The anode terminal of the organic EL element is connected to a power supply line 109 through an OLED (Organic Light-Emitting Diode) switch 107 and a channel of a driving TFT (Thin-Film-Transistor) 102. The gate of the driving TFT 102 is connected to a signal line 108 through a write capacitor 104 and a write switch 103 while a memory capacitor 105 is provided between the source terminal and the gate terminal of the driving TFT 102. And, a reset switch 106 is provided between the drain terminal and the gate terminal of the driving TFT 102. The OLED switch 107, the write switch 103, and the reset switch 106 are scanned by a scanning circuit provided at an end of the display area.

Next, the operation of the pixel shown in FIG. 18 will be described with reference to FIG. 19. FIG. 19 shows an operation timing chart of the pixel 110 in a conventional example. FIG. 19 denotes how the signal line 108, the reset switch 106, the OLED switch 107, and the write switch 103 will work when the pixel 110 is selected by the scanning circuit and a display signal is written in the pixel 110. The driving timing waveforms of the reset switch 106, the OLED switch 107, and the write switch are denoted as follows; the upper part denotes the switch OFF state and the lower part denotes the switch ON state respectively. When a display signal voltage is to be written in the pixel 110, at first the write switch 103 is turned on at t0 and a reference level signal voltage 0V is applied to one end of the write capacity 104. Then, the reset switch 106 is turned on at t1. Consequently, the driving TFT 102 comes to be connected as a diode in which the gate and the drain thereof are connected to each other, thereby the gate voltage of the driving TFT 102 stored in the memory capacitor 105 in the last field is cleared. After that, the OLED switch is turned off and the gate voltage of the driving TFT 102 rises up to a voltage that is lower than the supply voltage applied to the power supply line 109 only by the threshold voltage Vth. At this time, the current flowing in the driving TFT 102 stops. If the reset switch 106 is turned off after this state is stabilized, the gate voltage of the driving TFT 102 comes to be fixed at a voltage that is lower than the supply voltage applied to the power supply line 109 only by the threshold voltage Vth. And, if the voltage of the signal line 108 changes to the voltage Vs at t4, the gate voltage of the driving TFT 102 is shifted with respect to the above reset voltage only by a value obtained by multiplying the (Vs−V0) by a voltage dividing ratio between the write capacitor 104 and the memory capacitor 105. Then, when the write switch 103 is turned off at t5, this voltage is stored in the memory capacitor 105. This completes the writing of the display signal voltage in the pixel 110 and then the voltage of the signal line 108 goes back to the reference level signal voltage V0. And, when the OLED switch 107 is turned on at t7 again, the EL element 101 is driven to emit the light according to the driving current of the driving TFT 102 in response to a signal voltage inputted to its gate terminal. Consequently, the OLED emits the light corresponding to the (Vs−V0) signal voltage while the variation of the threshold voltage Vth existing in each pixel is canceled.

Such a conventional technique is described in detail in the non-patent document 1, Digest of Technical papers, SID 98, pp. 11-14.

### SUMMARY OF THE INVENTION

Generally, the OLED driving TFT 102 is a polycrystalline silicon TFT, which is varied more significantly in characteristics than the single crystalline silicon transistor. Particularly, the polycrystalline silicon TFT has a large variation of the threshold voltage Vth. The above conventional technique proposes a solution for the conventional problem that such a variation often occurs in display images.

However, the conventional technique must use four transistors and two capacitors per pixel to cancel the variation of the threshold voltage Vth as described above. The four transistors are used for a driving TFT 102, a reset switch 106, an OLED switch 107, and a write switch 103, and the two capacitors are used for a write capacitor 104 and a memory capacitor 105. Because such many elements are needed for each pixel in the conventional technique, yields of the electro-luminescent display devices come to fall, thereby the manufacturing cost increases. This has been a conventional problem. And, this problem has been caused by current leaks from transistor gate insulator films and each insulator film between capacitors that have resulted in point defects, as well as line defects in some cases to occur in electro-luminescent display devices.

The above conventional problem that yields of the electro-luminescent display elements fall due to the use of four transistors and two capacitors per pixel, thereby the manufacturing cost increases can be solved by providing the subject image display device with illuminating state controlling means for collectively controlling selection of the illuminating/not-illuminating state for each display part in which a display signal voltage is written and constant voltage supplying means for supplying a constant voltage to each pixel through a signal line. The image display device comprises a pixel having an electro-luminescent element driven to emit a light according to a display signal voltage; a display part consisting of a plurality of pixels; a signal line used to write a display signal voltage in each pixel; pixel selecting means for selecting a pixel from the plurality of pixels so as to write the display signal voltage therein; and display signal voltage generating means for generating the display signal voltage.

The above conventional problem may also be solved by providing the subject image display device with illuminating state controlling means for collectively controlling the selection of the illuminating/not-illuminating state of each display part in which a display signal voltage is written and triangular wave voltage supplying means for supplying a triangular wave voltage to each pixel through a signal line. In this aspect, the image display device comprises a pixel having an electro-luminescent element driven to emit a light according to a display signal voltage; a display part consisting of a plurality of pixels; a signal line used to write a display signal voltage in the pixel; image selecting means for selecting a pixel from the plurality of pixels so as to write the display signal voltage therein through a signal line; and display signal voltage generating means for generating a display signal voltage. And, one end of the electro-luminescent element provided in each pixel is connected to a common power supply while the other end thereof is connected to a drain electrode of the electro-luminescent element driving transistor and the source electrode of the light emission driving transistor is connected to a power supply line while the gate thereof is connected to the drain thereof through a third switch, and the gate of the electro-luminescent element driving transistor is connected to the signal line corresponding to each pixel through a connection capacitor.

### BRIEF DESCRIPTION OF THE DRAWINGS

FIG. 1 is an overall circuit diagram of an organic EL display panel in an embodiment of the present invention;

FIG. 2 is a circuit diagram of a pixel in the embodiment of the present invention;

FIG. 3 is an operation timing chart of the organic EL display panel in the embodiment of the present invention;

FIG. 4 is an operation timing chart of the pixel in the embodiment of the present invention;

FIG. 5 is a layout of the pixel in the embodiment of the present invention;

FIG. 6 is a circuit diagram of a pixel in the second embodiment of the present invention;

FIG. 7 is an overall circuit diagram of an organic EL display panel in the third embodiment of the present invention;

FIG. 8 is a circuit diagram of a pixel in the third embodiment of the present invention;

FIG. 9 is an operation timing chart of the organic EL display panel in the third embodiment of the present invention;

FIG. 10 is an operation timing chart of the pixel in the third embodiment of the present invention;

FIG. 11 is a layout of the pixel in the third embodiment of the present invention;

FIG. 12 is a circuit diagram of a pixel in the fourth embodiment of the present invention;

FIG. 13 is an overall circuit diagram of an organic EL display panel in the fifth embodiment of the present invention;

FIG. 14 is a circuit diagram of a pixel in the fifth embodiment of the present invention;

FIG. 15 is an operation timing chart of the organic EL display panel in the fifth embodiment of the present invention;

FIG. 16 is an operation timing chart of a row of pixels in the fifth embodiment of the present invention;

FIG. 17 is a block diagram of a TV image display device in the sixth embodiment of the present invention;

FIG. 18 is a circuit diagram of a pixel of an electro-luminescent display device according to a conventional technique; and

FIG. 19 is an operation timing chart of a pixel according to the conventional technique.

### DETAILED DESCRIPTION OF THE PREFERRED EMBODIMENTS

### First Embodiment

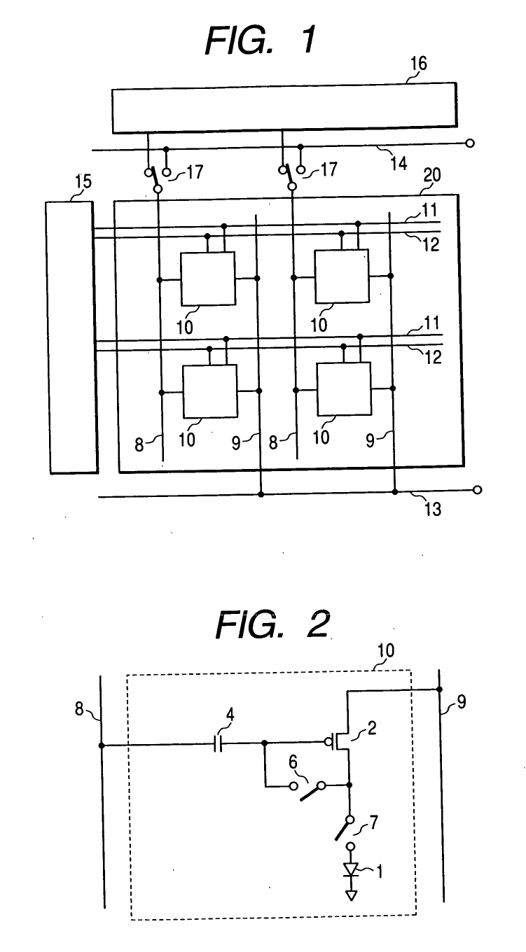

Hereunder, the first embodiment of the present invention will be described with reference to FIGS. 1 through 5.

At first, an overall configuration of this first embodiment will be described with reference to FIG. 1.

FIG. 1 shows an overall circuit diagram of an organic EL (electro-luminescent) display panel in this first embodiment. Pixels 10 are disposed like a matrix in a display area 20 and a signal line 8, a reset gate line 11, an OLED gate line 12, and a power supply line 9 are connected to each of the pixels 10. One end of the signal line 8 is connected to a signal voltage generation circuit 16 through a signal line switch 17. One end of each of the reset gate line 11 and the OLED gate line 12 is connected to a scanning circuit 15. One end of every power supply line 9 is connected to a power input line 13 and the signal line switch 17 switches the signal line 8 between the signal voltage generation circuit 16 and the constant voltage input line 14.

While a plurality of pixels 10 are provided in the display area 20 actually, FIG. 1 shows only four of them to simplify the drawing. And, while pixels are displayed in units of three (RGB); each pixel is provided with an illuminating function, although it is omitted here. Furthermore, as to be described later, a common ground electrode is wired to each pixel 10, although it is omitted here. The signal voltage generation circuit 16 is configured by a DA converter and a voltage buffer according to a well-known conventional LSI technique. The scanning circuit 15 is also formed on a glass substrate with a well-known shift register circuit and a proper logic circuit according to the polycrystalline silicon TFT technique.

Next, a structure of the pixel 10 will be described with reference to FIG. 2. FIG. 2 shows a circuit diagram of a pixel 10. Each pixel is provided with an organic EL element 1 that emits a light. The cathode terminal of the organic EL element 1 is connected to a common ground. The anode terminal of the organic EL element 1 is connected to a power supply line 9 through an OLED switch 7 and a channel of a driving TFT 2. The gate of the driving TFT 2 is connected to a signal line 8 through a memory capacitor 4 and a reset switch 6 is disposed between the drain terminal and the gate terminal of the driving TFT 2. The OLED switch 7 and the reset switch 6 are connected to the OLED gate line 12 and the reset gate line 11 respectively. The driving TFT 2, the OLED switch 7, and the reset switch 6 are configured by a polycrystalline silicon TFT respectively on a glass substrate. The manufacturing methods of the polycrystalline silicon TFT and the organic EL element 1 are not so much different from those having generally been reported so far, so that the description for them will be omitted here. The organic EL element 1 itself is disclosed in such conventional documents as JP-A No. 159878/2001.

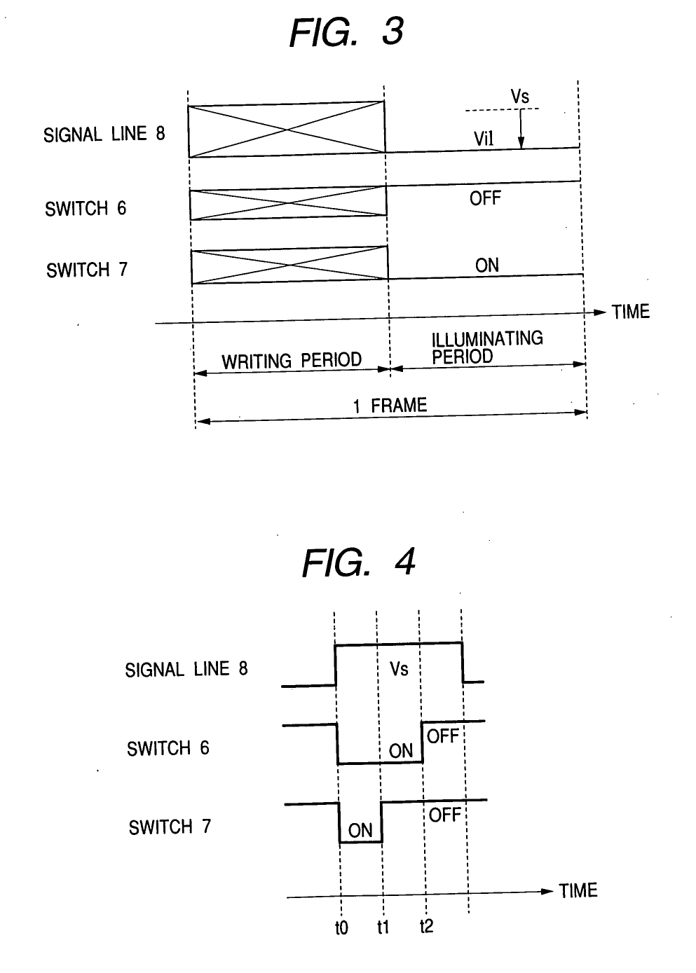

Next, the operation of the first embodiment will be described with reference to FIGS. 3 and 4. FIG. 3 shows an operation timing chart of the organic EL display panel in this first embodiment. FIG. 3 shows the operation of each of the signal line 8, the reset switch 6, and the OLED switch 7 in one frame period. The driving timing waveforms of the reset switch 6 and the OLED switch 7 are denoted as follows; the upper part denotes the switch off state and the lower part denotes the switch on state respectively. One frame period consists of a first half “writing period” and a second half “illuminating period” and both periods are almost equal in length.

In the first half “writing period”, the reset switch 6 and the OLED switch 7 in the pixel are driven sequentially in the order of scanning by the scanning circuit 15. Hereinafter, the operation of a pixel 10 selected by the scanning circuit 15 in the “writing period” will be described with reference to FIG. 4.

FIG. 4 shows an operation timing chart of the pixel 10 in this embodiment. The timing chart shows the operation of each of the signal line 8, the reset switch 6, and the OLED switch 7 when the pixel 10 is selected by the scanning circuit 15 and a display signal voltage is written therein. Just like in the above description, the driving timing waveforms of the reset switch 6 and the OLED 7 are denoted as follows; the upper part denotes the switch OFF state and the lower part denotes the switch ON state respectively. When a display signal voltage is written in the pixel 10, at first the reset switch 6 and the OLED switch 7 are turned on at t0 and a signal voltage Vs is applied to the signal line 8. Consequently, the driving TFT 2 comes to be connected as a diode in which the gate and the drain thereof are connected to each other, thereby the gate voltage of the driving TFT 2 stored in the storage capacitor 4 in the previous field is cleared. After that, the OLED switch 7 is turned off at t1, then the gate voltage of the driving TFT 2 rises up to a voltage that is lower then the supply voltage applied to the power supply line 9 only by the threshold voltage Vth, thereby the current flowing in the driving TFT 2 stops. If the reset switch 6 is turned off at t2 after this state is stabilized, the gate voltage of the driving TFT 2 is fixed at a voltage that is lower than the supply voltage applied to the power supply line 9 only by the threshold voltage Vth. In other words, when the signal voltage Vs is applied to the signal line 8 due to the writing in the storage capacitor 4, a voltage that is lower than the supply voltage applied to the source terminal only by the threshold voltage Vth through the power supply line 9 comes to appear again at the gate terminal of the driving TFT 2. Then, the display signal voltage writing in the pixel 10 is started, so that the signal voltage to be written in the pixel 10 is applied to the signal line 8. Repeating the above operations, the signal voltage is written all the target pixels 10, then the first half “writing period” is ended.

Next, a description will be made for the operation of the organic EL display panel in the second half “illuminating period” with reference to FIG. 3. In the second half “illuminating period”, a constant voltage Vil is applied to the signal line 8 and the reset switch 6 is fixed at OFF and the OLED switch 7 is fixed at ON for each pixel 10. If a signal voltage Vs is applied to the signal line 8 due to the writing in the storage capacitor 4, a voltage that is lower than the supply voltage applied to the source terminal only by the threshold voltage Vth appears again at the gate terminal of the driving TFT 2. On the other hand, if a constant voltage Vil is applied to the signal line 8 and the gate capacitor of the driving TFT 2 is small enough for the storage capacitor 4, a voltage that is lower than the supply voltage applied to the source terminal through the power supply line 9 only by the (Vs−Vil+threshold voltage |Vth|) comes to appear again at the gate terminal of the driving TFT 2. In other words, if a predetermined signal voltage Vs is written in each pixel beforehand, thereby the organic EL element 1 is driven to emit the light with the driving current of the driving TFT 2 free from influence of the variation of the threshold voltage Vth.

Thus, an advantage of the present invention is that it drives the OLED to illuminate corresponding to the (Vs−Vil) signal voltage while canceling the variation of the threshold voltage Vth of the driving TFT 2 existing in each pixel. This embodiment also has another advantage that can cancel the above variation of the threshold voltage Vth only with three transistors (the driving TFT 2, the reset switch 6, and the OLED switch 7) and one storage capacitor 4. Consequently, the number of elements per pixel is reduced, thereby yields of the electro-luminescent display devices are improved and the manufacturing cost is reduced in this embodiment.

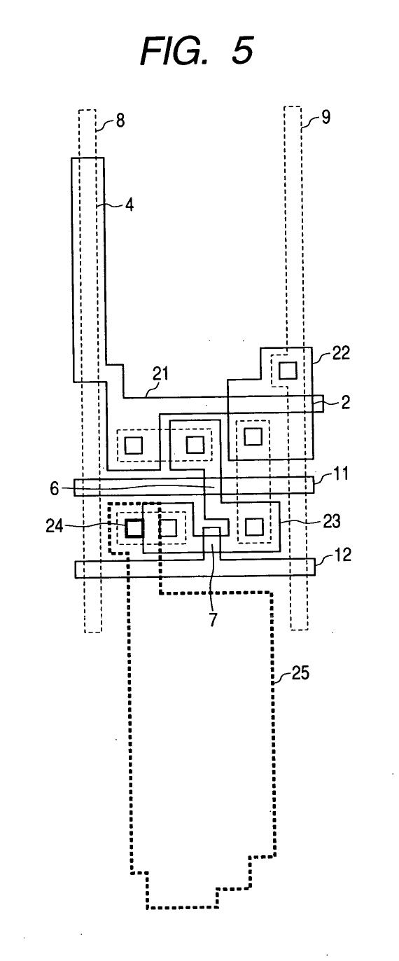

Next, a layout of the pixel 10 in this embodiment will be described with reference to FIG. 5.

FIG. 5 shows the layout of the pixel 10 in this embodiment. A thin broken line denotes AI wiring while a thick broken line denotes an ITO (Indium Tin Oxide) transparent electrode. A solid line denotes a polycrystalline silicon thin film island or TFT forming gate wiring. A thin line square denotes a contact hole for AI wiring and a polycrystalline thin film island or for AI wiring and a gate wiring. A thick line square denotes a contact hole for AI wiring and a transparent electrode.

The signal line 8 and the power supply line 9 are laid out with the AI wiring vertically at both right and left sides of the pixel 10. The gate wiring 21 is laid out so as to be overlapped with part of the signal line 8, thereby the part of the signal line 8 comes to be used as the storage capacitor 4 as is. Part of the gate wiring 21 is overlapped with the polycrystalline silicon thin film island 22 connected to the power supply line 9 so as to form the driving TFT 2. The polycrystalline silicon thin film island 23 connected to the gate wiring 21 forms the reset switch 6 at an intersection point with a reset gate 11 formed with the gate wiring and the OLED switch 7 at an intersection point with an OLED gate 12 formed with the same gate wiring respectively. The other end of the OLED switch 7 is connected to a transparent electrode 25 through the contact hole 24 for the AI wiring and the transparent electrode. An organic EL element 1 provided with an organic illuminating layer and a common ground is provided on the transparent electrode 25. Those items are general ones, so that the description for them is omitted here.

In the pixel layout in this embodiment, both signal line 8 and power supply line 9 are laid out with the AI wiring. The layout is especially effective to prevent the power supply line 9 from voltage drop. This is very important, since the driving current of the driving TFT 2 is affected by the source voltage thereof in this embodiment.

Furthermore, in the pixel layout in this embodiment, part of the signal line 8 is used as the storage capacitor 4 as is. Consequently, the area of the transparent electrode 25, as well as the area of the organic EL can be expanded, thereby the driving voltage required for the organic EL to illuminate can be reduced. And, while the storage capacitor 4 is formed by disposing the AI wiring and the gate wiring 21 in layers in this embodiment, the polycrystalline silicon thin film island connected to the AI wiring can also be used as needed to reduce the area of the storage capacitor 4.

The gate width of the driving TFT 2, when it is expanded enough, is effective to improve the quality of the display images. While the variation of the threshold voltage Vth of the driving TFT 2 is canceled as described above, it is impossible to cancel the drain conductance, as well as such a variation of the current driving performance as the field-effect mobility in this embodiment. To solve this problem, therefore, the gate width W of the driving TFT 2 should preferably be designed to satisfy the following.

W>Imax/10 nA

Here, the ‘Imax’ denotes the maximum current value to be assumed when the organic EL element 1 of the organic EL display panel is driven. With such a design, the driving TFT 2 comes to work in a sub-threshold region almost under the Vth. However, the diffusion current of the channel current of the field-effect transistor is dominant in the sub-threshold region, so that the driving current of the driving TFT 2 is hardly affected by the drain-source voltage, thereby the image quality comes to be free from the variation of the drain conductance described above.

While a description has been made for the first embodiment of the present invention, it is to be understood that modifications are possible without departing from the spirit of the invention. For example, while a glass substrate is used as the TFT substrate in this embodiment, the glass substrate may be replaced with another transparent insulated substrate such as a silicon substrate, transparent plastic substrate, or the like. If the light illuminated from the organic EL element 1 is taken out at the top of the element 1, a transparent substrate may be used as the TFT substrate.

In this embodiment, nothing is described for the number of pixels and panel sizes. This is because the present invention is not limited by those specification items nor any format. While the display signal voltage is defined in 64 gradation steps (6 bits), the voltage may also be defined in more gradation steps or less gradation steps easily.

Furthermore, in this embodiment, the scanning circuit 15 and the signal switch 17 are configured by a low temperature polycrystalline silicon TFT circuit respectively. However, both or one of those peripheral driving circuits may be configured by a single crystalline LSI (Large Scale Integrated Circuit) within the scope of the present invention. On the other hand, the signal voltage generation circuit 16 may also be configured by a low temperature polycrystalline silicon TFT circuit.

While the organic EL element 1 is used as an illuminating device in this embodiment, the EL element 1 may also be replaced with any of general electro-luminescent elements that include inorganic matters to realize the present invention.

Furthermore, in this embodiment, both of the first half “writing period” and the second half “illuminating period” are set almost equally in length in one frame. However, it also envisioned that other lengths may be used. This is because the luminance is improved while the signal writing is speeded up when the first half “writing period” is set short and the signal writing is slowed down while the luminance is lowered when the second half “illuminating period” is set short. In that connection, however, the first half “writing period” and the second half “illuminating period” should be adjusted properly in accordance with the use purpose of the organic EL display panel, of course.

Furthermore, in this embodiment, the organic EL element 1 is used as an electro-luminescent element. However, the concept of the present invention is not limited only to such an illuminating configuration; the present invention may apply to any of electro-luminescent elements, as well as inorganic EL elements.

Basically, various types of modifications as described above may apply to any other embodiments to be described below similarly.

### Second Embodiment

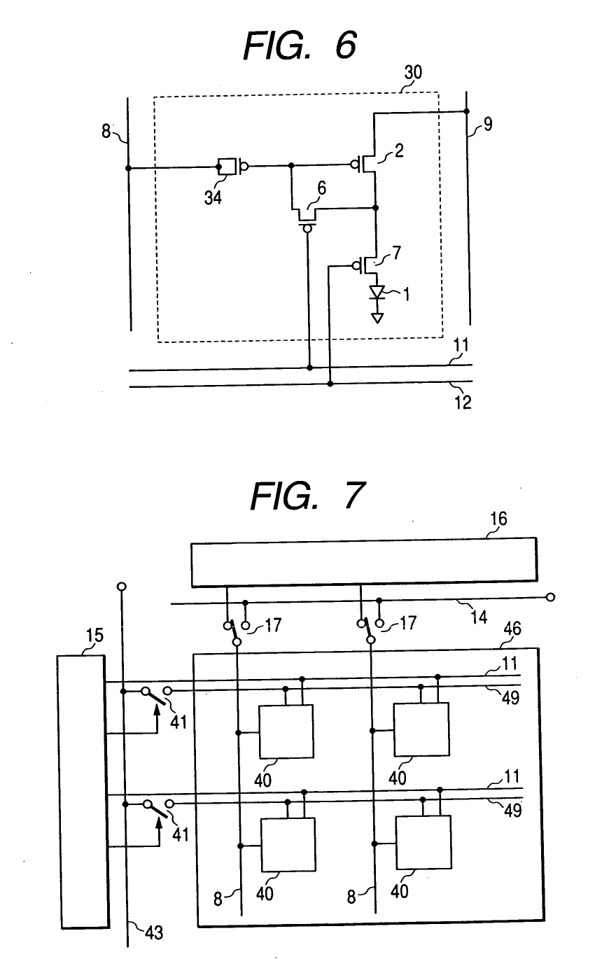

Next, the second embodiment of the present invention will be described with reference to FIG. 6.

Basically, both configuration and operation of this second embodiment is the same as those of the first embodiment except for the pixel structure. In this embodiment, therefore, the pixel structure will be described while the description for the same items as those in the first embodiment is omitted.

FIG. 6 shows a circuit diagram of a pixel of an organic EL display panel in the second embodiment of the present invention.

Each pixel 30 is provided with an organic EL element 1 used as an electro-luminescent element. The cathode terminal of the organic EL element 1 is connected to a common ground. The anode terminal of the element 1 is connected to a power supply line 9 through an OLED switch 7 and a channel of a driving TFT 2. The gate of the driving TFT 2 is connected to the signal line 8 through the storage capacitor 34 and a reset switch 6 is provided between the drain terminal and the gate terminal of the driving TFT 2. Particularly, in this second embodiment, each of the driving TFT 2, the OLED switch 7, and the reset switch 6, as well as the storage capacitor 34 is formed with a p-type polycrystalline silicon TFT on a glass substrate. In this embodiment, the signal voltage applied to the signal line 8 is set so as to become lower than the resetting time voltage of the driving TFT (the voltage of the power supply line 9−|Vth|). Consequently, a channel is always formed in the p-type polycrystalline silicon TFT used as the storage capacitor 34 so as to stabilize the gate capacitor.

In this second embodiment, every pixel is formed with a p-type polycrystalline silicon TFT. However, the scanning circuit 15 and the signal switch 17 may also be formed with a p-type polycrystalline silicon TFT respectively. In that connection, the n-type high concentration implanting process can be omitted. This is why the manufacturing process can be simplified, thereby the manufacturing cost can be reduced.

### Third Embodiment

Hereunder, the third embodiment of the present invention will be described with reference to FIGS. 7 through 11.

At first, an overall configuration of an organic EL display panel in this third embodiment will be described with reference to FIG. 7. Pixels 40 are disposed like a matrix in a display area 46. And, a signal line 8, a reset gate line 11, and a power supply line 49 are connected to each of the pixels 40. One end of the signal line 8 is connected to a signal voltage generation circuit 16 through a signal switch 17 and one end of the reset gate line 11 is connected to the scanning circuit 45. The power supply lines 49 are all connected to a power input line 43 through a power supply line switch 41 respectively. Each of the power supply line switches 41 is controlled by the scanning circuit 45 while the signal line switch 17 switches the signal line 8 between the signal voltage generation circuit 16 and the constant voltage input line 14.

While many pixels are disposed in the display region 46 actually, only four of them are shown in FIG. 7 to simplify the drawing. As to be described later, a common ground electrode is also wired in each pixel 40, although it is omitted in the drawing. The signal voltage generation circuit 16 is configured by a DA converter and a voltage buffer using a conventional well-known LSI technique. The scanning circuit 45 is also configured by a known shift register circuit and a proper logic circuit on a glass substrate using the polycrystalline silicon TFT technique.

Next, a structure of the pixel 40 will be described with reference to FIG. 8.

FIG. 8 shows a circuit diagram of the pixel 40. Each pixel is provided with an organic EL element 1 used as an electro-luminescent element. The cathode terminal of the organic EL element 1 is connected to a common ground and the anode terminal of the element 1 is connected to a power supply line 49 through a channel of the driving TFT 2. And, a reset switch is provided between the drain terminal and the gate terminal of the driving TFT 2. The reset switch 6 is connected to the reset gate line 11 described above. The driving TFT 2 and the reset switch 6 are formed with a polycrystalline silicon TFT respectively on a glass substrate. The manufacturing methods of the polycrystalline silicon TFT and the organic EL element 1 are general conventional ones, so that the description for them will be omitted here.

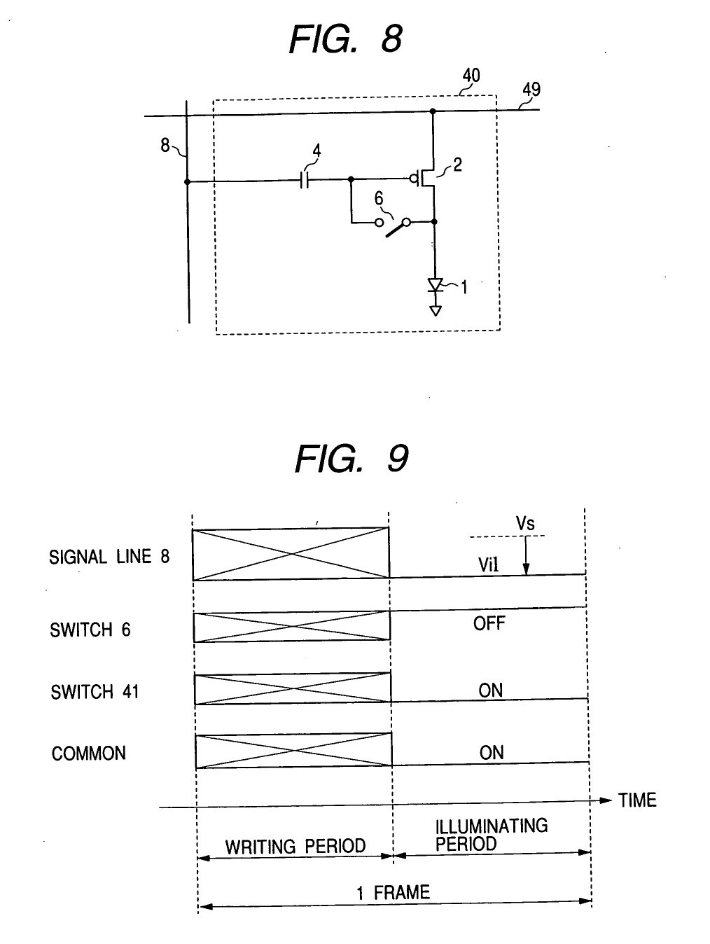

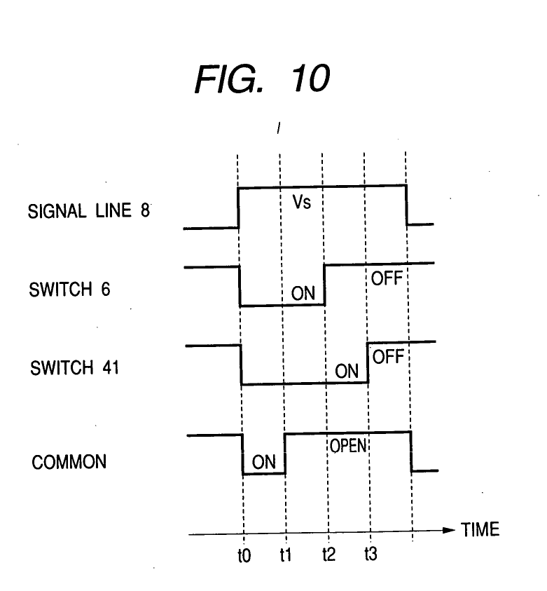

Next, a description will be made for the operation of the organic EL display panel in the third embodiment of the present invention with reference to FIGS. 9 and 10.

FIG. 9 shows an operation timing chart of each of the signal line 8, the reset switch 6, the power supply switch 41, and the common ground (Common) to which the cathode terminal of the organic EL element 1 is connected in one frame period. The driving timing waveforms of the reset switch 6 and the power switch 41 are denoted as follows; the upper part denotes the switch OFF state while the lower part denotes the switch ON state respectively. The common ground operation is denoted as follows; the lower part denotes the grounded state while the upper part denotes the floating (Open) state. One frame period consists of a first half “writing period” and a second half “illuminating period”. Both first half and second half are set almost equally in length. In the first half “writing period”, the reset switch 6 in the pixel 40 and the power supply line switch 41 provided at an end of the display area 46 are driven sequentially in the order of scanning by the scanning circuit 45 and the common ground state is kept changed alternately between grounding and floating. Hereinafter, a description will be made for the operation of a row of pixels 40 selected by the scanning circuit 45 in a “writing period” with reference to FIG. 10.

FIG. 10 shows an operation timing chart of the row of the pixels 40 in this third embodiment. The timing chart shows the operation of each of the signal line 8, the reset switch 6, the power switch 41, and the common ground (Common) to which the cathode terminal of the organic EL element 1 is connected when the row of the pixels 40 is selected by the scanning circuit 45 and a display signal voltage is written in the row. Similarly to the above embodiment, the driving timing waveforms of the reset switch 6 and the power supply line switch 41 are denoted as follows; the upper part denotes the switch OFF state while the lower part denotes the switch ON state respectively. The operation state of the common ground (Common) is also denoted as follows; the upper part denotes the floating (Open) state and the lower part denotes the grounded state. When a display signal voltage is to be written in a pixel 40, at first the reset switch 6 and the power supply line switch 41 are turned on at t0 and the common ground is grounded, thereby the signal voltage Vs is applied to the signal line 8. Consequently, the driving TFT 2 is connected as a diode in which the gate and the drain thereof are connected to each other, thereby the gate voltage of the driving TFT 2 stored in the storage capacitor 4 in the previous field is cleared. After that, the common ground goes into the floating state (Open) and the current flowing in the driving TFT 2 stops when the gate voltage of the driving TFT 2 rises up to a voltage that is lower than the supply voltage applied to the power supply line 49 only by the threshold voltage Vth. Consequently, if the reset switch 6 is turned off at t2 after the state is stabilized, the gate voltage of the driving TFT 2 is fixed at a voltage that is lower than the supply voltage applied to the power supply line 49 only by the threshold voltage Vth. This means that a voltage that is lower than the supply voltage applied to the source terminal through the power supply line 9 only by the threshold voltage Vth comes to appear again at the gate terminal of the driving TFT 2 when the signal voltage Vs is applied to the signal line 8. After that, the power supply line switch 41 is turned off at t3 and the writing of the signal voltage in this row is completed.

After that, writing of the display signal voltage in the next row of pixels 40 is started and a signal voltage to be written in the next pixel 40 is applied to the signal line 8. Repeating the above operations, the signal voltage is written in every pixel 40 and the first half “writing period” is ended.

Next, the operation of the organic EL display panel in the second half “illuminating period” will be described with reference to FIG. 9. In the second half “illuminating period”, a constant voltage Vil is applied to the signal line 8, then the reset switch 6 is turned off, the power supply line switch 41 is turned on, and the common ground is fixed at the ground voltage for all the pixels 40 at the same time. When the signal voltage Vs is applied to the signal line 8, a voltage that is lower than the supply voltage applied to the source terminal through the power supply line 49 only by the threshold voltage Vth appears again at the gate terminal of the driving TFT 2. On the other hand, when a constant voltage Vil is applied to the signal line 8, if the gate capacitor of the driving TFT 2 is small enough with respect to the storage capacitor 4, a voltage that is lower than the supply voltage applied to the source terminal through the power supply line 49 only by the (Vs−Vil+threshold voltage |Vth|) appears again at the gate terminal of the driving TFT 2. This means that writing a predetermined signal voltage Vs in each pixel beforehand enables the organic EL element 1 to be driven to illuminate with the driving current of the driving TFT 2 free from the influence of the variation of the threshold voltage Vth.

Thus an advantage of the present invention is that it can drive the OLED to illuminate corresponding to the (Vs−Vil) signal voltage while canceling the variation of the threshold voltage Vth of the driving TFT 2 existing in each pixel in this third embodiment. This third embodiment can also cancel the variation of the threshold voltage Vth as described above only with two transistors (the driving TFT 2 and the reset switch 6) and one storage capacitor 4 provided in each pixel. As a result, the number of elements per pixel is reduced, thereby yields of the electro-luminescent display devices are improved and the manufacturing cost of the devices is reduced.

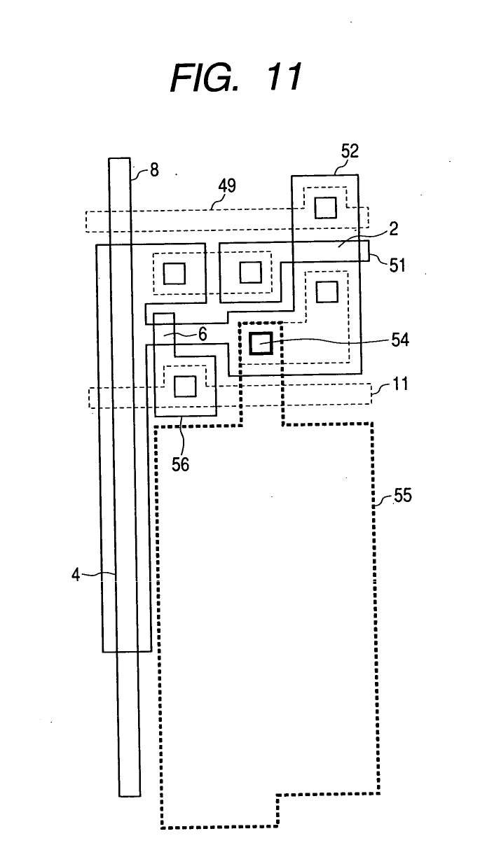

Next, a layout of the pixel 40 in this third embodiment will be described with reference to FIG. 11.

FIG. 11 shows the layout of the pixel 40 in this third embodiment. In FIG. 11, a thin broken line denotes AI wiring, a thick broken line denotes a transparent electrode that uses ITO (Indium Tin Oxide), and a solid line denotes a polycrystalline silicon thin film island or TFT forming gate wiring. A thin line square denotes a contact hole for AI wiring and a polycrystalline silicon thin film island or for AI wiring and gate wiring. A thick line square denotes a contact hole for AI wiring and a transparent electrode.

The signal line 8 is laid out with the gate wiring at one end of the pixel 40 vertically and the power supply line 49 is laid out with the AI wiring vertically to the signal line 8. And, a polycrystalline silicon thin film island 52 is provided so as to be overlapped with part of the signal line 8, so that the part of the signal line 8 is used as the storage capacitor as is. The polycrystalline silicon thin film island 52 forms the reset switch at an intersection point with the gate wiring connected to the reset switch 11 and the driving TFT 2 at an intersection point with the gate wiring 51 connected to the end. Part of the polycrystalline silicon thin film 52 is also connected to the transparent electrode 55 through the contact hole for the AI wiring and the transparent electrode. The organic EL element 1 provided with an organic illuminating layer, a cathode common ground, etc. is provided on the transparent electrode 55. The structures of those items are common ones, so that the description for them will be omitted here.

In the layout of the pixel 40 in this embodiment, the power supply line 49 is laid out with the AI wiring in the row direction, so that the power supply line 49 can be prevented from voltage drop. In this third embodiment, the driving current of the driving TFT 2 is affected by the source voltage thereof, so that it is important to prevent the power supply line 49 from voltage drop such way.

Also in the pixel layout in this embodiment, part of the signal line 8 is used as the storage capacitor 40 as is. Consequently, the area of the transparent electrode can be expanded, thereby the area of the organic EL can be expanded. As a result, the driving voltage required for the organic EL illuminating is reduced.

### Fourth Embodiment

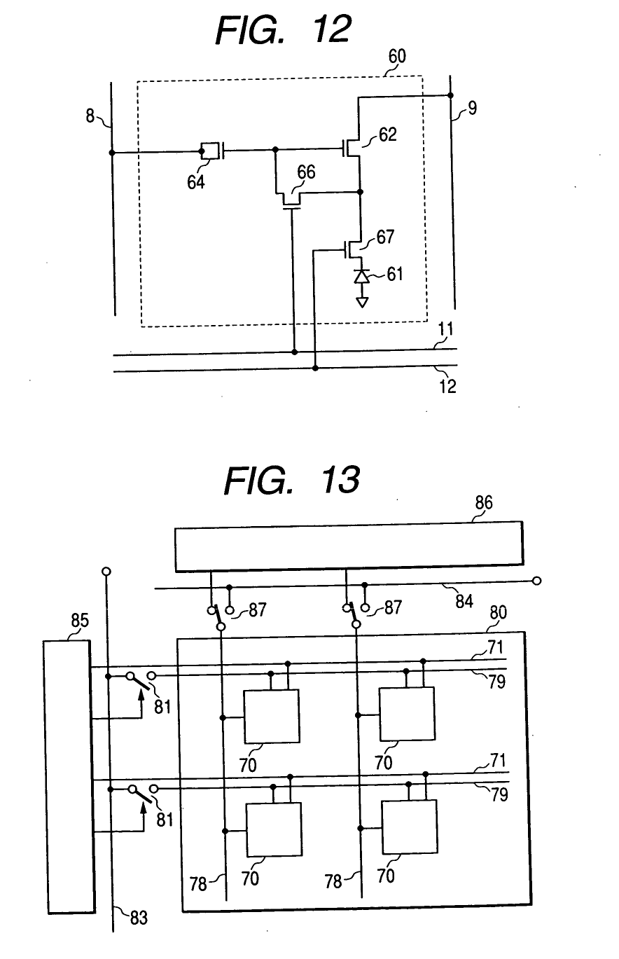

Hereunder, an organic EL display panel in the fourth embodiment of the present invention will be described with reference to FIG. 12.

Basically, both configuration and operation of the organic EL display panel in this fourth embodiment are the same as those of the first embodiment except for the pixel structure. Therefore, explanations for the same items as those in the first embodiment will be omitted and only the pixel structure will be described here.

FIG. 12 shows a circuit diagram of a pixel of the organic EL display panel in this fourth embodiment of the present invention. Each pixel 60 is provided with an organic EL element 61 used as an electro-luminescent element. The anode terminal of the organic EL element 61 is connected to a common ground and the cathode terminal of the element 61 is connected to a power supply line 9 through an OLED switch 67 and a channel of a driving TFT 62. And, the gate of the driving TFT 62 is connected to a signal line 8 through a storage capacitor 64 and a reset switch 66 is provided between the drain terminal and the gate terminal of the driving TFT 62. In this fourth embodiment, each of the driving TFT 62, the OLED switch 67, the reset switch 66, and the storage capacitor 64 are formed specially with an n-type amorphous silicon TFT on a glass substrate. In that connection, the signal voltage applied to the signal line 8 is set so as to become lower than the resetting time voltage of the driving TFT 62 (the voltage of the power supply line 9+|Vth|). Consequently, a channel is always formed at the n-type amorphous silicon TFT used as the storage capacitor 64, thereby the gate capacitor is usable as a stable capacitor.

And, while every pixel is formed with an n-type amorphous silicon TFT in this embodiment, the scanning circuit 15 and the signal switch 17 may also be formed with an n-type amorphous silicon TFT respectively. Therefore, the process for obtaining polycrystalline silicon can be omitted. It is thus possible to simplify the manufacturing method and reduce the manufacturing cost.

Furthermore, while the gate electrode of the storage capacitor 64 is provided at the pixel side in this fourth embodiment, it may also be provided at the signal line side. In that connection, however, the signal voltage applied to the signal line 8 must be set higher than the resetting time voltage of the driving TFT 62 (the voltage of the power supply line 9+|Vth|).

### Fifth Embodiment

Next, the fifth embodiment of the present invention will be described with reference to FIGS. 13 through 16. At first, an overall configuration of an organic EL display panel in this fifth embodiment will be described with reference to FIG. 13.

FIG. 13 shows an overall block diagram of the organic EL display panel in this fifth embodiment. Pixels 70 are disposed like a matrix in a display area 80. A signal line 78, a reset gate line 71, and a power supply line 79 are connected to each of the pixels 70. One end of the signal line 78 is connected to a signal voltage generation circuit 86 through a signal switch 87 and one end of the reset gate line 71 is connected to a scanning circuit 85, and the power supply lines 79 are all connected to a power supply input line 83 through the power supply line switch 81 respectively. The power supply line switches 81 are controlled by the scanning circuit 85 and the signal switch 87 switches the signal line 78 between the signal voltage generation circuit 86 and the triangular wave input line 84.

While many pixels 70 are provided in the display area 80 actually, only four of them 70 are described in the display area so as to simplify the drawing. As to be described later, a common electrode is connected to each pixel 70, although it is omitted in the drawing. The signal voltage generation circuit 86 is configured by a DA converter and a voltage buffer circuit using a well-known conventional LSI technique while the scanning circuit 85 is configured by a known shift register circuit and a proper logic circuit on a glass substrate using a polycrystalline silicon TFT technique.

Next, a structure of the pixel 70 will be described with reference to FIG. 14.

FIG. 14 shows a circuit diagram of the pixel 70. Each pixel 70 is provided with an organic EL element 1 used as an electro-luminescent element. The cathode terminal of the organic EL element 1 is connected to a common ground and the anode terminal of the element 1 is connected to a power supply line 79 through a channel of the driving TFT 72. And, the gate of the driving TFT 72 is connected to a signal line 78 through a storage capacitor 74 and a reset switch 76 is provided between the drain terminal and the gate terminal of the driving TFT 72. In this fifth embodiment, the reset switch 76 is connected to a reset gate line 71. Each of the driving TFT 72 and the reset switch 76 is formed with a polycrystalline silicon TFT on a glass substrate

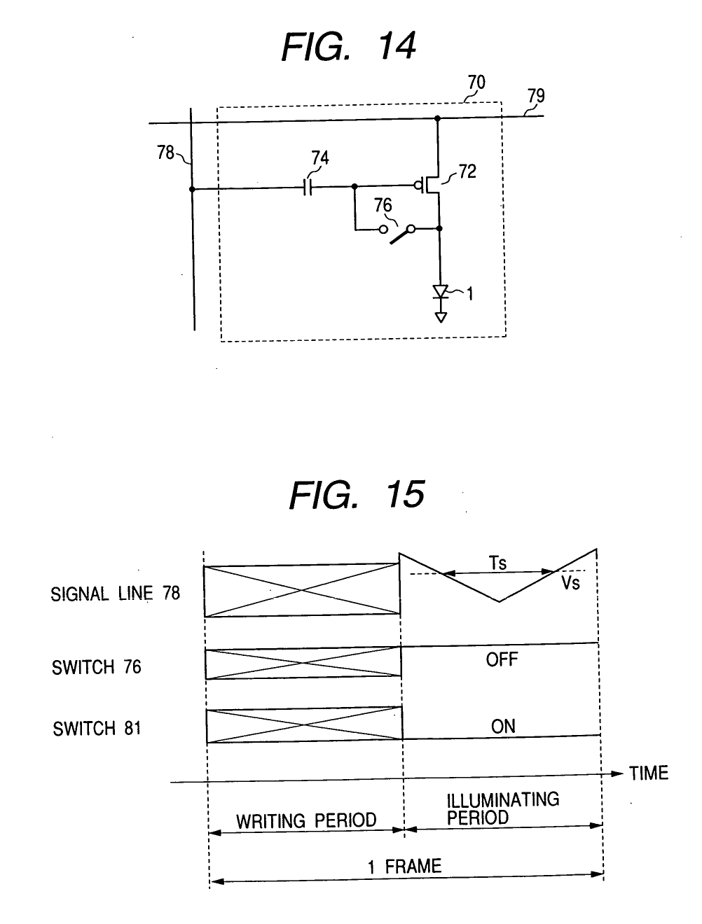

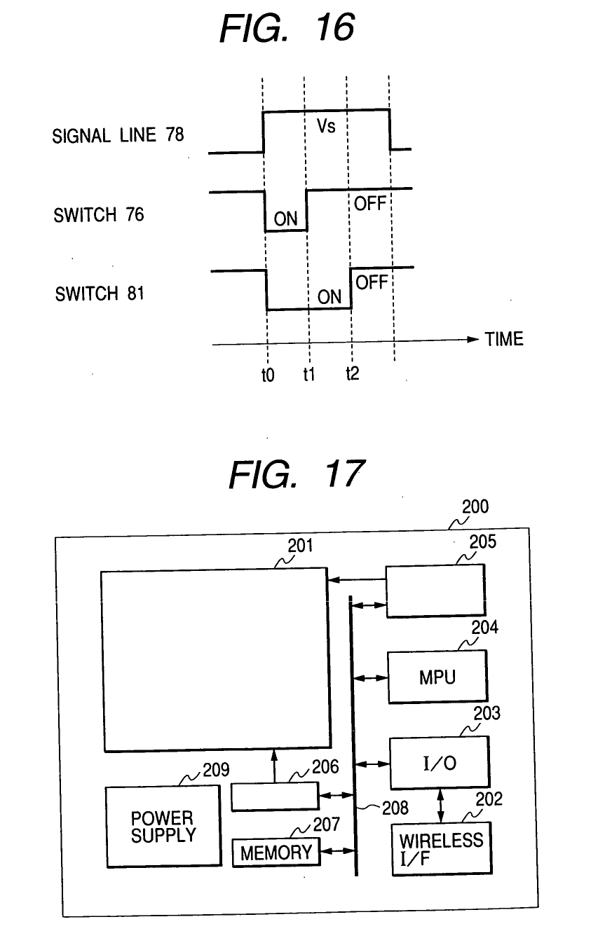

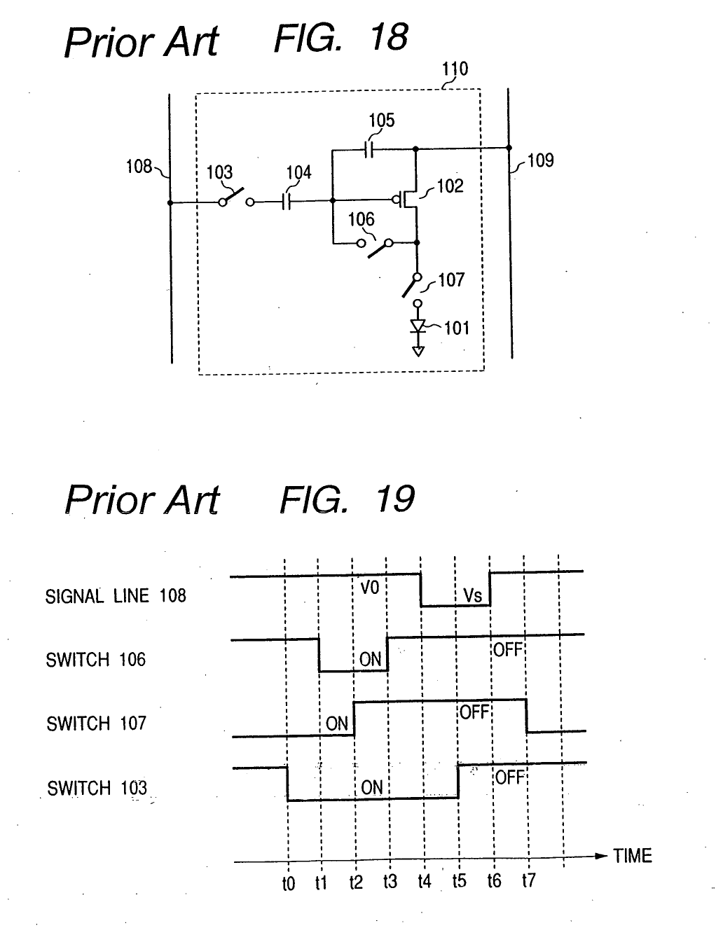

Next, the operation of the organic EL display panel in the fifth embodiment will be described with reference to FIGS. 15 and 16.

FIG. 15 shows an operation timing chart of the organic EL display panel in this fifth embodiment; the chart denotes the operation of each of the signal line 78, the reset switch 76, and the power supply switch 81 in one frame period. The driving timing waveforms of the reset switch 76 and the power supply line switch 81 are denoted as follows; the upper part denotes the switch OFF state while the lower part denotes the switch ON state respectively. One frame period consists of a first half “writing period” and a second half “illuminating period”. Both first half and second half are set almost equally in length. In the first half “writing period”, the reset switch 76 in the pixel 70 and the power supply line switch 81 provided at an end of the display area 80 are driven sequentially in the order of scanning by the scanning circuit 85. Hereinafter, a description will be made for the operation of the EL display panel during the “writing period” for a row of pixels 70 selected by the scanning circuit 85 with reference to FIG. 16.

FIG. 16 shows an operation timing chart of the row of pixels 70 in this fifth embodiment; the chart denotes the operation of each of the signal line 78, the reset switch 76, and the power supply line switch 81 when the row of the pixels 70 is selected by the scanning circuit 85 and a display signal voltage is written in the row. The driving timing waveforms of the reset switch 76 and the power supply line switch 81 are denoted as follows; the upper part denotes the switch OFF state and the lower part denotes the switch ON state respectively just like in the above examples.

When a display signal voltage is to be written in a pixel 70, at first the reset switch 76 and the power supply line switch 81 are turned on at t0, thereby the signal voltage Vs is applied to the signal line 78. Consequently, the driving TFT 2 is connected as a diode in which the gate and the drain thereof are connected to each other, thereby the gate voltage of the driving TFT 2 stored in the storage capacitor 74 in the previous field is cleared. The pixel circuit may be regarded as an inverter circuit in which the driving TFT 2 is replaced with a driving transistor and the organic EL element 1 is replaced with a load. In that connection, the input terminal and the output terminal of this inverter circuit are short-circuited by the reset switch 76 in and after t0. Consequently, an intermediate voltage between the “high voltage output” and the “low voltage output” of the inverter circuit is generated at the input and output terminals of the inverter circuit. If the reset switch 76 is turned off at t1, the gate voltage of the driving TFT 2 is fixed approximately at an intermediate voltage between the “high voltage output” and the “low voltage output” of the inverter circuit. The “high voltage output” means a supply voltage applied to the power supply line 79 while the “low voltage output” means a common ground voltage. In other words, if the signal voltage Vs is applied to the signal line 78 due to the writing in the storage capacitor 74, an intermediate voltage between the “high voltage output” and the “low voltage output” of the inverter circuit output appears again at the gate terminal of the driving TFT 2. After that, the power supply line switch 81 is turned off at t2 to complete the writing of the signal voltage in that row.

After that, writing of the display signal voltage in the next row of pixels is started and the signal voltage to be written in the next pixel is applied to the signal line 78. Repeating the above operations, the signal voltage is written in every pixel 70 of the row and the first half “writing period” is ended.

Next, a description will be made for the operation of the organic EL display panel in the second half “illuminating period” with reference to FIG. 15. In the second half “illuminating period”, a triangular wave that obtains the lowest voltage in its center part as shown in FIG. 15 is applied to the signal line 78. The reset switch 76 is fixed at OFF and the power supply line switch 81 is fixed at ON for all the pixels 40 of the row at the same time. When the signal voltage Vs is applied to the signal line 78 due to the writing in the storage capacitor 74 as described above, the inverter circuit in which the driving TFT 2 is replaced with a driving transistor and the organic EL element 1 is replaced with a load outputs an intermediate voltage. If a voltage higher than the signal voltage Vs is applied to the signal line 78, however, the inverter circuit outputs the “low voltage” (common ground voltage). If a voltage lower than the signal voltage Vs is applied to the signal line 78, the inverter circuit outputs the “high voltage” (supply voltage applied to the power supply line 79). Consequently, the “high voltage” (supply voltage applied to the power supply line 79) is applied to the organic EL element 1 of the pixel 70 in the period Ts in which the voltage of the signal line 78 becomes lower than the signal voltage Vs written in the pixel 70 beforehand as shown in FIG. 15, thereby the EL element 1 illuminates. In other words, the organic EL element 1 actually takes a binary state of illuminating/not-illuminating and the illuminating period Ts is controlled by the signal voltage Vs to illuminate in gradation steps.

Thus an advantage of the present invention is that can drive the OLED to illuminate corresponding to the signal voltage Vs while canceling the variation of the threshold voltage Vth of the driving TFT 2 existing in each pixel. However, this embodiment can further obtain another effect that cancels the above variation of the threshold voltage Vth only with two transistors (the driving TFT 2 and the reset switch 6) and one storage capacitor 4 provided in each pixel. As a result, the number of elements per pixel is reduced, and thereby yields of the electro-luminescent display devices are improved and the manufacturing cost of the devices is reduced. Furthermore, this embodiment has still another advantage that can also cancel the variation of the current driving performance of the driving TFT 2, since the organic EL element 1 is actually driven in the binary state of illuminating/non-illuminating.

The layout of the pixel 70 in this embodiment is basically the same as that in the third embodiment. The description for the layout will thus be omitted here. In this embodiment, however, it is recognized that the wider the gate of the driving TFT 2 is, the more sharply the inverter characteristics of the pixel circuit comes to rise, thereby the variation of the logical threshold value of the inverter circuit is reduced. In this case, however, note that if the gate of the driving TFT 2 is expanded in width, the storage capacitor 74 must also be expanded accordingly.

As described above, a single triangular wave is applied to the signal line in the “illuminating period” in this embodiment. However, the wave may be configured by a plurality of triangles. And, if the triangular wave is shaped non-linearly, proper gamma characteristics can also be given to display images.

Furthermore, in this embodiment, the power supply line 79 is shared by pixels of TGB three colors. However, it is also possible to provide the power supply line 79 with a plurality of channels to enable the driving voltage of the organic EL element 1 to be changed for each illuminating color, thereby controlling and changing the color balance properly.

### Sixth Embodiment

Hereunder, the sixth embodiment of the present invention will be described with reference to FIG. 17.

FIG. 17 is a block diagram of a TV image display device 200 in this sixth embodiment.

A radio interface (I/F) circuit 202 for receiving ground wave digital signals, etc. receives an input of such radio communication data as compressed image data from external. The radio interface (I/F) circuit 202 outputs data to a data bus 208 through an I/O (Input/Output) circuit 203. A microprocessor (MPU) 204, a display panel controller 206, a frame memory 207, etc. are also connected to the data bus 208. The output of the display panel controller 206 is inputted to an organic EL display panel 201. An image display terminal 200 is provided with a constant voltage generation circuit 205 and a power supply 209. The output of the constant voltage generation circuit 205 is inputted to the organic EL display panel 201. Both configuration and operation of the organic EL display panel 201 are the same as those of the organic EL display panel in the first embodiment, so that the description for them will be omitted here.

Hereunder, the operation of the TV image display device in the sixth embodiment will be described. At first, the radio I/F circuit 202 receives compressed image data from external in response to a command inputted by the user, then transfers the image data to both of the microprocessor 204 and the frame memory 207 through the I/O circuit 203. The microprocessor 204, when receiving a command from the user, drives the whole image display terminal 200 as needed to decode the compressed image data, processes the signals, and display the information. In that connection, the signal-processed image data may be stored in the frame memory 207 temporarily.

If the microprocessor issues a display command at that time, the image data is inputted to the organic EL display panel 201 from the frame memory through the display panel controller 206 according to the command, then the organic EL display panel 201 displays the received image data in real time. At that time, the display panel controller 206 outputs a predetermined timing pulse required to display the image data and the constant voltage generation circuit 205 outputs a predetermined constant voltage, which is varied to adjust the quality of images. The organic EL display panel 201 uses those signals to display the data generated from the 6-bit image data in real time just like in the first embodiment. The power supply 209 that includes a secondary battery supplies a power for driving the whole image display terminal 200.

According to this sixth embodiment, therefore, it is possible to provide an image display terminal 200 for enabling high precision multiple gradation display of images.

While the organic EL display panel described in the first embodiment is used as an image display device in this sixth embodiment, it may be replaced with any of other various display panels as described in other embodiments of the present invention. In that connection, however, the circuit configuration might be required to be modified according to the structure of the organic EL display panel. For example, if the organic EL display panel described in the fifth embodiment is used, the constant voltage generation circuit 205 must be replaced with a triangular wave voltage generation circuit.

According to the present invention, it is possible to provide an image display device for enabling high quality image display and realizing high yields of the image display devices, thereby reducing the manufacturing cost of the image display devices.

What is claimed is:

1. An image display device comprising:
a first pixel comprising a first electro-luminescent element driven to illuminate according to a first display signal voltage, a first driving TFT whose first current terminal is connected to a first terminal of the first electro-luminescent element, and a first storage capacitor whose first terminal is connected to a gate terminal of the first driving TFT;
a second pixel comprising a second electro-luminescent element driven to illuminate according to a second display voltage, a second driving TFT whose current terminal is connected to a first terminal of the second electro-luminescent element, and a second storage capacitor whose first terminal is connected to a gate of the second driving TFT;
a first power supply line supplying a supply voltage to the first electro-luminescent element via a channel of the first driving TFT or supplying the supply to the second electro-luminescent element via a channel of the second driving TFT; and
a power supply line scanning circuit scanning the first power supply line.

2. An image display device according to claim 1, further comprising:
a power supply input line connected to the first power supply line via a first power supply line switch,
wherein the power supply line controls the first power supply line switch.

3. An image display device according to claim 1,
wherein the first pixel further comprises a first reset switch connecting the first current terminal of the first driving TFT and the gate terminal of the first driving TFT,
wherein the second pixel further comprises a second reset switch connecting the first current terminal of the second driving TFT and the gate terminal of the second driving TFT.

4. An image display device according to claim 2, further comprising:
a third pixel comprising a third electro-luminescent element driven to illuminate according to a third display signal voltage, a third driving TFT whose first current terminal is connected to a first terminal of the first electro-luminescent element, and a third storage capacitor whose first terminal is connected to a gate of the third driving TFT;
a fourth pixel comprising a fourth electro-luminescent element driven to illuminate according to a fourth display signal voltage, a fourth driving TFT whose first current terminal is connected to a first terminal of the fourth electro-luminescent element, and a fourth storage capacitor whose first terminal is connected to a gate of the fourth driving TFT;
a second power supply line connected to the power supply input line via a second supply line switch, supplying the supply voltage to the third electro-luminescent element via a channel of the third driving TFT, and supplying the supply voltage to the fourth electro-luminescent element via a channel of the fourth driving TFT;
a signal voltage generation circuit supplying the first display signal voltage to the first electro-luminescent element, supplying the second display signal voltage to the second electro-luminescent element, supplying the third display signal voltage to the third electro-luminescent element, and supplying the fourth display signal voltage to the fourth electro-luminescent element;
a driving wave input line supplying a driving wave voltage to the first capacitor, the second capacitor, the third capacitor, and the fourth capacitor;
a first signal line connected to a second terminal of the first capacitor and a second terminal of the third capacitor;
a second signal line connected to a second terminal of the second capacitor and a second terminal of the fourth capacitor;
a first signal switch selecting to connect the first signal line and the signal voltage generation circuit or to connect the first signal line and the driving wave input line; and
a second signal switch selecting to connect the second signal line and the signal voltage generation circuit or to connect the second signal line and the driving wave input line.

5. An image display device according to claim 4,
wherein a wave form of the driving wave voltage is one triangular wave.

6. An image display device according to claim 4,
wherein a wave form of the driving wave voltage is repeated in each frame period.
